(19) United States
(12) Patent Application Publication
(10) Pub. No.: US 2015/0372204 A1
(43) Pub. Date: Dec. 24, 2015

(54) ULTRAVIOLET LIGHT EMITTING DEVICE

(71) Applicant: Panasonic Intellectual Property Management Co.,Ltd, Osaka (JP)

(72) Inventors: KOUICHIROU MATSUOKA, Kyoto (JP); KAZUHIKO HAYASHI, Osaka (JP); SHINTARO HAYASHI, Hyogo (JP)

(21) Appl. No.: 14/763,164

(22) PCT Filed: Jan. 27, 2014
(86) PCT No.: PCT/JP2014/000391

§ 371 Date: Jul. 23, 2015

(30) Foreign Application Priority Data
Jan. 31, 2013 (JP) 2013-016531
Jan. 31, 2013 (JP) 2013-016532

(51) Int. Cl. H01L 33/60; H01L 33/48

(52) U.S. Cl. CPC H01L 33/60; H01L 33/483

(57) ABSTRACT

An ultraviolet light emitting device of the present invention includes a light emitting element provided on a substrate, an optical system provided at a position facing the light emitting element, a metal cylinder holding the optical system, and a holding component holding the metal cylinder on a substrate. Light the emitting element is disposed in an area of the substrate, the area surrounded by one end of the metal cylinder closer to the substrate. This provides the ultraviolet light emitting device that prevents the distortion of the optical system as well as the influence of ultraviolet light on the holding component.

### TECHNICAL FIELD

The present invention relates to an ultraviolet light emitting device using a light source generating ultraviolet light.

### BACKGROUND ART

Light emitting devices have been disclosed that include a light emitting element, a reflector, an optical system, and a holding component (refer to PTL 1 for instance). The light emitting element is provided on the substrate. The reflector is provided on the substrate so as to surround the light emitting element. The optical system is provided at a position facing the light emitting element. The holding component holds the optical system on the substrate.

In recent years, various types of light emitting devices are available, such as an ultraviolet light emitting device with its light emitting element using a light source (e.g., UV-LED, excimer lamp) generating ultraviolet light.

Usually, an ultraviolet light emitting device undergoes distortion and discoloration in its optical system under the influence of ultraviolet light generated from the light emitting element. To prevent them, the optical system is made of a material such as glass with a low coefficient of expansion.

The above-described ultraviolet light emitting device, however, holds its optical system with a holding component. Accordingly, if the coefficients of expansion are different between the optical system and the holding component, the holding component may cause the optical system to be distorted when the device is used in an environment the temperature changes for example.

Further, in the above-described ultraviolet light emitting device, its optical system is held at a position away from the reflector by the holding component. Accordingly, ultra violet light generated from the light emitting element is diffused from between the optical system and the reflector to illuminate the holding component and other parts. Consequently, the emitted ultraviolet light undesirably causes the deterioration and degradation of the holding component.

### Citation List

### PTL

PTL 1 Japanese Patent Unexamined Publication No. 2007-59378

### SUMMARY OF THE INVENTION

Under the circumstances, the present invention provides an ultraviolet light emitting device that prevents the distortion of the optical system and suppresses the influence on the holding component due to ultraviolet light generated from the light emitting element.

Specifically, an ultraviolet light emitting device of the present invention includes a light emitting element provided on the substrate, an optical system provided at a position facing the light emitting element, a metal cylinder holding the optical system, and a holding component having an insert hole for holding the metal cylinder on a substrate. Then, the light emitting element is disposed in an area of the substrate, the area surrounded by one end of the metal cylinder closer to the substrate.

With this structure, the metal cylinder is held on the substrate by the holding component. Then, the light emitting element is placed in an area surrounded by the end closer to the substrate, of the metal cylinder, on the substrate. Accordingly, of the ultraviolet light generated from the light emitting element, the ultraviolet light that travels outward in the radial direction of the metal cylinder strikes the inside of the metal cylinder to proceed toward the optical system while changing its traveling direction. After all, the ultraviolet light that travels outward in the radial direction of the metal cylinder is shaded by the metal cylinder. This prevents the ultraviolet light generated from the light emitting element from illuminating the holding component, which prevents the deterioration and degradation of the holding component.

### BRIEF DESCRIPTION OF DRAWINGS

FIG. 1 is a perspective view of an ultraviolet light emitting device according to a first exemplary embodiment of the present invention.

FIG. 2 is a longitudinal sectional view of the ultraviolet light emitting device according to the first exemplary embodiment.

FIG. 3 is a longitudinal sectional view of an ultraviolet light emitting device according to a second exemplary embodiment of the present invention.

FIG. 4 is a longitudinal sectional view of an ultraviolet light emitting device according to a third exemplary embodiment of the present invention.

FIG. 5 is a longitudinal sectional view of an ultraviolet light emitting device according to a fourth exemplary embodiment of the present invention.

### DESCRIPTION OF EMBODIMENTS

Hereinafter, a description is made of an ultraviolet light emitting device according to some exemplary embodiments of the present invention, with reference to the related drawings. Note that the exemplary embodiments do not limit the scope of the present invention.

### First Exemplary Embodiment

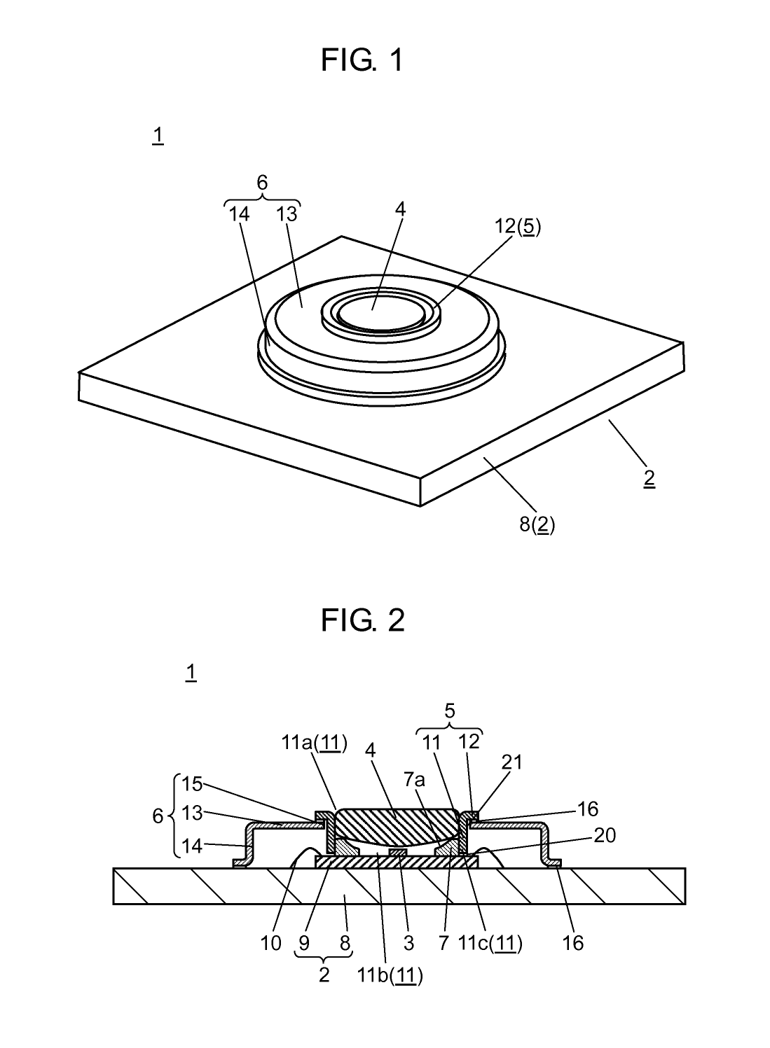

Hereinafter, a description is made of an ultraviolet light emitting device according to the first exemplary embodiment of the present invention, referring to FIGS. 1 and 2.

FIG. 1 is a perspective view of an ultraviolet light emitting device of the first exemplary embodiment of the present invention. FIG. 2 is a longitudinal sectional view of the ultraviolet light emitting device.

As shown in FIGS. 1 and 2, ultraviolet light emitting device 1 of this exemplary embodiment at least includes substrate 2, light emitting element 3, optical system 4, metal cylinder 5, holding component 6, and reflector 7. Substrate 2 is composed of base substrate 8 and interposer 9. Light emitting element 3 is provided on interposer 9 of substrate 2. Optical system 4 is provided at a position facing light emitting element 3. Metal cylinder 5 includes cylinder body 11 and flange 12 to hold optical system 4. Holding component 6 holds metal cylinder 5 on substrate 2. Reflector 7, provided on interposer 9 of substrate 2, includes reflecting surface 7a surrounding the periphery of light emitting element 3.

An electric circuit is built on base substrate 8 of substrate 2. Then, interposer 9 of substrate 2 electrically connects light emitting element 3 with base substrate 8. Concretely, interposer 9 is disposed on base substrate 8 of substrate 2, and base substrate 8 and interposer 9 are electrically connected to each other through wiring material 10. This electrically connects light emitting element 3 disposed on interposer 9 with base substrate 8. Here, interposer 9 of substrate 2 is fixed onto base substrate 8 through a conductive paste such as Ag paste.

Light emitting element 3 such as a UV-LED generates ultraviolet light. Light emitting element 3 is placed in an area (in the projection area of metal cylinder 5) surrounded by end 11c closer to substrate 2, of cylinder body 11 of metal cylinder 5, on interposer 9 of substrate 2. Note that, in this exemplary embodiment, light emitting element 3 is placed in an area surrounded by reflector 7 provided in contact with the inner surface of cylinder body 11 of metal cylinder 5, on interposer 9 of substrate 2.

As described above, metal cylinder 5 includes tubular cylinder body 11 and flange 12 extending from cylinder body 11 outward in the radial direction, formed in a reverse L-shape in a cross-sectional view shown in FIG. 2. Then, metal cylinder 5 is made of a metal having a coefficient of expansion identical to or substantially identical to that of optical system 4. Concretely, metal cylinder 5 is made of Kovar.

Cylinder body 11 of metal cylinder 5 has first open end 11a (closer to flange 12); and second open end 11b opposite to first open end 11a, in the direction of the center line. Optical system 4 is inserted into first open end 11a of cylinder body 11. Then, opening 20 is provided between end 11c closer to second open end 11b, of cylinder body 11, and interposer 9 of substrate 2. With this structure, end 11c closer to second open end 11b, of cylinder body 11 is placed facing interposer 9.

Flange 12 of metal cylinder 5 is provided on the entire outer circumference of cylinder body 11 closer to first open end 11a.

Optical system 4, made of a material such as glass with a small coefficient of expansion, is inserted into metal cylinder 5 near flange 12 so as to plug first open end 11a. Concretely, optical system 4 is made of glass such as quartz glass.

Holding component 6, provided with supporting part 13 and fixing part 14, faces base substrate 8 of substrate 2 and interposer 9. Supporting part 13 supports metal cylinder 5 from the outer circumference of cylinder body 11 of metal cylinder 5. Fixing part 14 is connected to supporting part 13 and is fixed onto base substrate 8 of substrate 2.

Further, supporting part 13 of holding component 6 is formed in a round plate shape in a planar view from above as shown in FIG. 1, and has insert hole 15 piercing in the direction orthogonal (perpendicular) to the surface shown in FIG. 2, in the central part of supporting part 13. The hole diameter of insert hole 15 is determined in a range larger than the outer circumference of cylinder body 11 of metal cylinder 5 and smaller than flange 12 of metal cylinder 5. With this setting, opening 21 is formed between supporting part 13 and cylinder body 11 inserted into insert hole 15.

When cylinder body 11 of metal cylinder 5 is inserted into insert hole 15 of supporting part 13, flange 12 of metal cylinder 5 is disposed so as to overlap the part around insert hole 15, of supporting part 13. In this exemplary embodiment, flange 12 is fixed to supporting part 13 (the part around insert hole 15, of supporting part 13) of holding component 6, at least in an area overlapping with flange 12 of metal cylinder 5, through elastic bonding material 16 such as silicone. With this structure, flange 12 of metal cylinder 5 is fixed to the top of holding component 6 slightly movably with respect to holding component 6 through bonding material 16.

Meanwhile, fixing part 14 of holding component 6 is provided on the entire outer circumferential edge of supporting part 13. Then, similarly to supporting part 13, fixing part 14 is fixed to base substrate 8 of substrate 2 through bonding material 16.

Further, as shown in FIG. 2, reflector 7 is mounted on interposer 9 of substrate 2 and is fitted to the inside of metal cylinder 5. Resultingly, entire reflector 7 is disposed at least in an area where reflecting surface 7a corresponds to the inside of metal cylinder 5 on substrate 2. More concretely, reflector 7 is fitted to a part near cylinder body 11 closer to second open end 11b, of metal cylinder 5. At this moment, reflector 7 is provided so as to plug opening 20 between second open end 11b of cylinder body 11 of metal cylinder 5 and interposer 9 of substrate 2. Resultingly, the inside space and the outside space, of metal cylinder 5 are partitioned off from each other.

With the above process, ultraviolet light emitting device 1 of this exemplary embodiment is configured.

Hereinafter, a description is made of relationship between ultraviolet light generated from light emitting element 3 and each component of ultraviolet light emitting device 1, in ultraviolet light emitting device 1 of this exemplary embodiment, referring to FIG. 2.

First, of the ultraviolet light generated from light emitting element 3, the ultraviolet light heading toward reflector 7 is reflected on reflecting surface 7a of reflector 7. Then, the reflected ultraviolet light proceeds toward first open end 11a of cylinder body 11 of metal cylinder 5.

Meanwhile, of the ultraviolet light generated from light emitting element 3, the ultraviolet light that travels outward in the radial direction of metal cylinder 5 strikes the inner circumferential surface of metal cylinder 5, and undergoes reflection and diffusion to proceed toward first open end 11a of cylinder body 11 while changing its traveling direction.

Under all of the circumstances, the ultraviolet light generated from light emitting element 3 reaches optical system 4 without leaking from the inside of metal cylinder 5 to the outside around metal cylinder 5. Subsequently, the ultraviolet light passes through optical system 4 and is emitted from first open end 11a of cylinder body 11 of metal cylinder 5 toward the outside space.

As described above, in ultraviolet light emitting device 1 of this exemplary embodiment, metal cylinder 5 holding optical system 4 is made of a metal (e.g., Kovar) having a coefficient of expansion identical to or substantially identical to that of optical system 4. Accordingly, even if optical system 4 and metal cylinder 5 expand under the influence of temperature change caused by changes of the outside environment, metal cylinder 5 and optical system 4 expand and contract to the same extent. This prevents the distortion of optical system 4 due to the expansion and contraction of metal cylinder 5.

With ultraviolet light emitting device 1 of this exemplary embodiment, metal cylinder 5 is held by holding component 6 on interposer 9 of substrate 2. Further, light emitting element 3 is disposed in an area surrounded by end 11c closer to substrate 2, of cylinder body 11 of metal cylinder 5, on interposer 9 of substrate 2. This allows metal cylinder 5 to shade ultraviolet light that travels outward in the radial direction of metal cylinder 5. This prevents ultraviolet light from illuminating holding component 6 disposed at the part of metal cylinder 5 closer to its outer circumference. Resultingly, a holding component does not need to be made of a special resin or metal, unlike an existing ultraviolet light emitting device, thereby achieving a low-cost ultraviolet light emitting device. Further, the exemplary embodiment suppresses the influence (e.g., deterioration and degradation) on holding component 6 by ultraviolet light, thereby achieving a highly reliable ultraviolet light emitting device.

With ultraviolet light emitting device 1 of this exemplary embodiment, flange 12 of metal cylinder 5 is fixed to the top of holding component 6. Accordingly, there is no opening between flange 12 and holding component 6, which prevents the generated ultraviolet light from being diffracted around metal cylinder 5 to reach substrate 2. This suppresses the influence of ultraviolet light on substrate 2.

With ultraviolet light emitting device 1 of this exemplary embodiment, flange 12 of metal cylinder 5 is fixed (e.g., elastically) to the top of supporting part 13 near insert hole 15 of holding component 6 through elastic bonding material 16. Accordingly, flange 12 can be fixed to the top of holding component 6 in a state where flange 12 and holding component 6 are slightly movable from each other. This allows a stress acting on metal cylinder 5 to be damped owing to the deformation for example of bonding material 16 even if holding component 6 expands and contracts. Consequently, the distortion of optical system 4 generated by the deformation and movement of holding component 6 can be effectively suppressed.

Further, the top of bonding material 16 that fixes flange 12 of metal cylinder 5 to holding component 6 enters a state covered with flange 12 of metal cylinder 5. This prevents ultraviolet light from illuminating bonding material 16. This suppresses the influence (e.g., deterioration and degradation) of ultraviolet light on bonding material 16.

With ultraviolet light emitting device 1 of this exemplary embodiment, opening 21 is provided between cylinder body 11 of metal cylinder 5 and holding component 6. This prevents holding component 6 from immediately contacting metal cylinder 5 even if holding component 6 expands. This allows a stress acting on metal cylinder 5 to be damped even if holding component 6 expands. Consequently, the distortion of optical system 4 generated by the deformation and movement of holding component 6 can be effectively suppressed.

With ultraviolet light emitting device 1 of this exemplary embodiment, reflector 7 plugs opening 20 between second open end 11b of cylinder body 11 and interposer 9. This prevents the generated ultraviolet light from light emitting element 3 from leaking through opening 20 between substrate 2 and metal cylinder 5, thereby more reliably preventing ultraviolet light from illuminating holding component 6.

With ultraviolet light emitting device 1 of this exemplary embodiment, light emitting element 3 and at least reflecting surface 7a of reflector 7 are disposed in an area surrounded by cylinder body 11 closer to end 11c, of metal cylinder 5, on interposer 9 of substrate 2. Further, optical system 4 plugs first open end 11a of cylinder body 11 of metal cylinder 5.

In other words, the space between light emitting element 3 and optical system 4 is partitioned by metal cylinder 5. Accordingly, of the ultraviolet light generated from light emitting element 3, the ultraviolet light that travels outward in the radial direction of metal cylinder 5 strikes the inner circumferential surface of metal cylinder 5 to proceed while changing its traveling direction, reaching optical system 4. This prevents ultraviolet light from illuminating holding component 6. Resultingly, holding component 6 does not need to be made of a special resin or metal, thereby achieving low-cost ultraviolet light emitting device 1. Further, ultraviolet light can be effectively led to optical system 4 without the ultraviolet light being dispersed.

With ultraviolet light emitting device 1 of this exemplary embodiment, reflector 7 is fitted to the inside of metal cylinder 5 in a contacted manner. This prevents ultraviolet light generated from the light emitting element from dispersing. Further, heat from light emitting element 3 can be discharged by metal cylinder 5. Concretely, with metal cylinder 5 in contact with reflector 7, heat generated in light emitting element 3 is transmitted to metal cylinder 5 through reflector 7 as radiant heat, thereby discharging heat of light emitting element 3 through metal cylinder 5.

Further, heat can be discharged from light emitting element 3 without providing a component for discharging heat of light emitting element 3 from a part closer to substrate 2. This eliminates the need for insulating substrate 2 from light emitting element 3, unlike in a case where substrate 2 is made of metal for instance, which simplifies the structure of substrate 2.

### Second Exemplary Embodiment

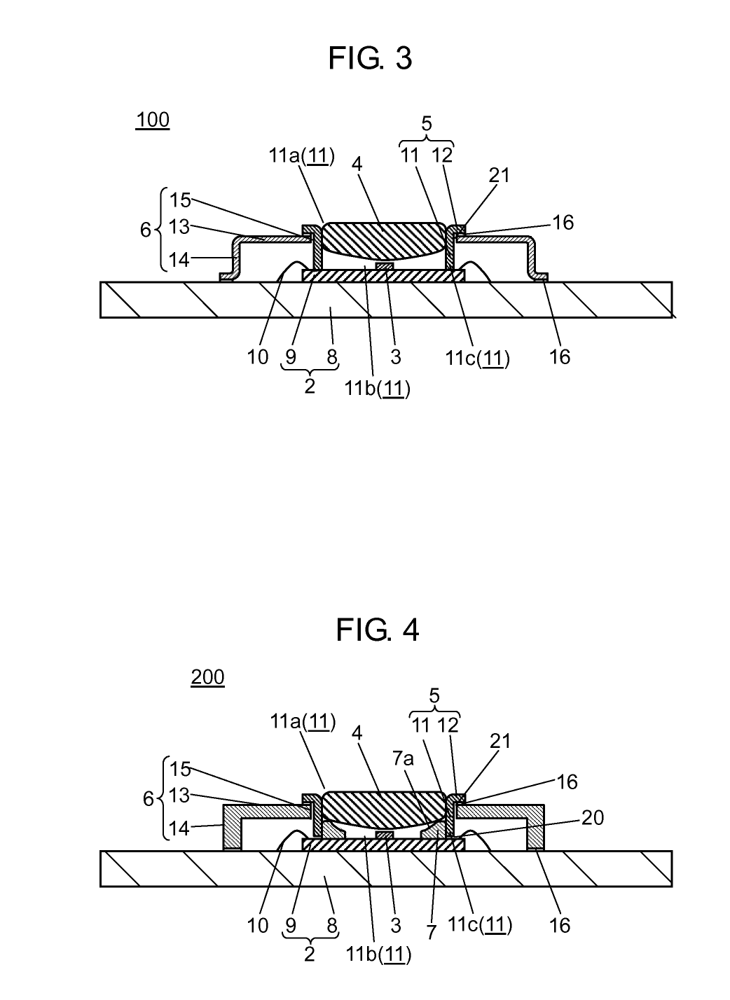

Hereinafter, a description is made of ultraviolet light emitting device 100 according to the second exemplary embodiment of the present invention, referring to FIG. 3.

FIG. 3 is a longitudinal sectional view of an ultraviolet light emitting device according to the second exemplary embodiment of the present invention.

Ultraviolet light emitting device 100 of this exemplary embodiment is different from ultraviolet light emitting device 1 of the first exemplary embodiment in that a reflector is not provided and end 11c of cylinder body 11 of metal cylinder 5 is directly mounted on interposer 9 of substrate 2. Otherwise, ultraviolet light emitting device 100 is the same as ultraviolet light emitting device 1 of the first exemplary embodiment. Hence, a component same as or similar to that of ultraviolet light emitting device 1 is given the same reference mark, and a description is made quoting from the first exemplary embodiment.

As shown in FIG. 3, ultraviolet light emitting device 100 of this exemplary embodiment is at least composed of light emitting element 3 provided on substrate 2, optical system 4 provided at a position facing light emitting element 3, metal cylinder 5 holding optical system 4, and holding component 6 holding metal cylinder 5 on substrate 2. Note that substrate 2, light emitting element 3, optical system 4, metal cylinder 5, and holding component 6 have basic structures same as those of the first exemplary embodiment.

Metal cylinder 5 includes tubular cylinder body 11 and flange 12 extending from cylinder body 11 outward in the radial direction, formed in a reverse L-shape in a cross-sectional view shown in FIG. 3. Then, metal cylinder 5 is made of a metal (e.g., Kovar) having a coefficient of expansion identical to or substantially identical to that of optical system 4.

Further, cylinder body 11 of metal cylinder 5 has first open end 11a (closer to flange 12); and second open end 11b opposite to first open end 11a, in the direction of the center line. Optical system 4 is inserted into first open end 11a of cylinder body 11. Then, end 11c closer to second open end 11b, of cylinder body 11 is mounted on interposer 9 of substrate 2 in a contacted manner.

Accordingly in this exemplary embodiment, light emitting element 3 is disposed in an area surrounded by metal cylinder 5, on interposer 9 of substrate 2.

Note that flange 12 of metal cylinder 5 and holding component 6 have structures same as those of the first exemplary embodiment.

With the above process, ultraviolet light emitting device 100 of this exemplary embodiment is configured.

Hereinafter, a description is made of relationship between ultraviolet light generated from light emitting element 3 and each component of ultraviolet light emitting device 100, in ultraviolet light emitting device 100 of this exemplary embodiment, referring to FIG. 3.

First, of the ultraviolet light generated from light emitting element 3, the ultraviolet light that heads outward in the radial direction of metal cylinder 5 strikes the inner circumferential surface of metal cylinder 5, and undergoes reflection and diffusion to proceed toward first open end 11a of cylinder body 11 while changing its traveling direction. Resultingly, the ultraviolet light passes through optical system 4 and is emitted toward the outside space of metal cylinder 5.

As described above, in ultraviolet light emitting device 100 of this exemplary embodiment, metal cylinder 5 holding optical system 4 is made of a metal (e.g., Kovar) having a coefficient of expansion identical to or substantially identical to that of optical system 4. Accordingly, even if optical system 4 and metal cylinder 5 expand under the influence of temperature change caused by changes of the outside environment, metal cylinder 5 and optical system 4 expand and contract to the same extent. This prevents the distortion of optical system 4 due to the expansion and contraction of metal cylinder 5.

With ultraviolet light emitting device 100 of this exemplary embodiment, metal cylinder 5 is held by holding component 6, on interposer 9 of substrate 2. Further, light emitting element 3 is disposed in an area surrounded by end 11c closer to substrate 2, of cylinder body 11 of metal cylinder 5, on interposer 9 of substrate 2. This allows metal cylinder 5 to shade ultraviolet light that travels outward in the radial direction of metal cylinder 5. This prevents ultraviolet light from illuminating holding component 6 disposed at the part of metal cylinder 5 closer to its outer circumference. Resultingly, a holding component does not need to be made of a special resin or metal, unlike an existing ultraviolet light emitting device, thereby achieving a low-cost ultraviolet light emitting device. Further, the exemplary embodiment suppresses the influence (e.g., deterioration and degradation) of ultraviolet light on holding component 6, thereby achieving a highly reliable ultraviolet light emitting device.

With ultraviolet light emitting device 100 of this exemplary embodiment, flange 12 of metal cylinder 5 is fixed to the top of holding component 6. Accordingly, there is no opening between flange 12 and holding component 6, which prevents ultraviolet light generated from light emitting element 3 from being diffracted around metal cylinder 5 to reach substrate 2. This suppresses the influence of ultraviolet light on substrate 2.

With ultraviolet light emitting device 100 of this exemplary embodiment, flange 12 of metal cylinder 5 is fixed (e.g., elastically) to the top of supporting part 13 near insert hole 15 of holding component 6 through elastic bonding material 16. Accordingly, flange 12 can be fixed to the top of holding component 6 in a state where flange 12 and holding component 6 are slightly movable from each other. This allows a stress acting on metal cylinder 5 to be damped owing to the deformation for example of the bonding material even if holding component 6 expands. Consequently, the distortion of optical system 4 generated by the deformation and movement of holding component 6 can be effectively suppressed.

Further, the top of bonding material 16 that fixes flange 12 of metal cylinder 5 to holding component 6 enters a state covered with flange 12 of metal cylinder 5. This prevents ultraviolet light from illuminating bonding material 16. This suppresses the influence (e.g., deterioration and degradation) of ultraviolet light on bonding material 16.

With ultraviolet light emitting device 100 of this exemplary embodiment, opening 21 is provided between cylinder body 11 of metal cylinder 5 and holding component 6. This prevents holding component 6 from immediately contacting metal cylinder 5 even if holding component 6 expands. This allows a stress acting on metal cylinder 5 to be damped even if holding component 6 expands. Consequently, the distortion of optical system 4 generated by the deformation and movement of holding component 6 can be effectively suppressed.

With ultraviolet light emitting device 100 of this exemplary embodiment, end 11c closer to second open end 11b, of cylinder body 11 of metal cylinder 5 is held on interposer 9 of substrate 2 by holding component 6 in a contacted manner. This prevents ultraviolet light generated from light emitting element 3 from leaking through the opening between interposer 9 of substrate 2 and end 11c of cylinder body 11 of metal cylinder 5, thereby more reliably preventing ultraviolet light from illuminating holding component 6.

Ultraviolet light emitting device 100 dispenses with a reflector to simplify the structure.

### Third Exemplary Embodiment

Hereinafter, a description is made of ultraviolet light emitting device 200 according to the third exemplary embodiment of the present invention, referring to FIG. 4.

FIG. 4 is a longitudinal sectional view of an ultraviolet light emitting device according to the third exemplary embodiment of the present invention.

Ultraviolet light emitting device 200 of this exemplary embodiment is different from ultraviolet light emitting device 1 of the first exemplary embodiment in that the holding component is made of a resin material. Otherwise, ultraviolet light emitting device 200 is the same as ultraviolet light emitting device 1 of the first exemplary embodiment. Hence, a component same as or similar to that of ultraviolet light emitting device 1 is given the same reference mark, and a description is made quoting from the first exemplary embodiment.

As shown in FIG. 4, ultraviolet light emitting device 200 of this exemplary embodiment is at least composed of light emitting element 3 provided on substrate 2, optical system 4 provided at a position facing light emitting element 3, metal cylinder 5 holding optical system 4, holding component 6 holding metal cylinder 5 on substrate 2, and reflector 7.

Note that substrate 2, light emitting element 3, optical system 4, metal cylinder 5, and reflector 7 have basic structures same as those of the first exemplary embodiment.

In this exemplary embodiment, holding component 6 is made of a moldable resin such as Duracon. Then, holding component 6, including supporting part 13 and fixing part 14, is provided facing base substrate 8 of substrate 2 and interposer 9. Supporting part 13 supports metal cylinder 5 from the outer circumference of cylinder body 11 of metal cylinder 5. Fixing part 14, connected to supporting part 13, is fixed onto base substrate 8 of substrate 2 through bonding material 16.

Further, supporting part 13 of holding component 6 is formed in a round plate shape in a planar view from above, similarly as described using FIG. 1, and has insert hole 15 piercing in the direction orthogonal (perpendicular) to the surface, in the central part of supporting part 13. The hole diameter of insert hole 15 is determined in a range larger than the outer circumference of cylinder body 11 of metal cylinder 5 and smaller than flange 12 of metal cylinder 5. With this setting, opening 21 is formed between supporting part 13 and cylinder body 11 inserted into insert hole 15. When cylinder body 11 of metal cylinder 5 is inserted into insert hole 15 of supporting part 13, flange 12 of metal cylinder 5 is disposed so as to overlap the part around insert hole 15, of supporting part 13.

In this exemplary embodiment as well, flange 12 is fixed to supporting part 13 (the part around insert hole 15, of supporting part 13) of holding component 6, at least in an area overlapping with flange 12 of metal cylinder 5, through elastic bonding material 16 such as silicone. With this structure, flange 12 of metal cylinder 5 is fixed to the top of holding component 6 slightly movably with respect to holding component 6 through bonding material 16.

Meanwhile, fixing part 14 of holding component 6 is provided on the entire outer circumferential edge of supporting part 13. Then, similarly to supporting part 13, fixing part 14 is fixed to base substrate 8 of substrate 2 through bonding material 16.

With the above process, ultraviolet light emitting device 200 of this exemplary embodiment is configured.

Hereinafter, a description is made of relationship between ultraviolet light generated from light emitting element 3 of ultraviolet light emitting device 200 and each component of ultraviolet light emitting device 200, of this exemplary embodiment, referring to FIG. 4.

First, of the ultraviolet light generated from light emitting element 3, the ultraviolet light heading toward reflector 7 is reflected on reflecting surface 7a of reflector 7, similarly to ultraviolet light emitting device 1 of the first exemplary embodiment. Then, the reflected ultraviolet light proceeds toward first open end 11a of cylinder body 11 of metal cylinder 5.

Meanwhile, of the ultraviolet light generated from light emitting element 3, the ultraviolet light that travels outward in the radial direction of metal cylinder 5 strikes the inner circumferential surface of metal cylinder 5, and undergoes reflection and diffusion to proceed toward first open end 11a of cylinder body 11 while changing its traveling direction.

Under all of the circumstances, the ultraviolet light generated from light emitting element 3 reaches optical system 4 without leaking from the inside of metal cylinder 5 to the outside around metal cylinder 5. Subsequently, the ultraviolet light passes through optical system 4 and is emitted from first open end 11a of cylinder body 11 of metal cylinder 5 toward the outside space.

As described above, in ultraviolet light emitting device 200 of this exemplary embodiment, metal cylinder 5 holding optical system 4 is made of a metal (e.g., Kovar) having a coefficient of expansion identical to or substantially identical to that of optical system 4. Accordingly, even if optical system 4 and metal cylinder 5 expand under the influence of temperature change caused by changes of the outside environment, metal cylinder 5 and optical system 4 expand and contract to the same extent. This prevents the distortion of optical system 4 due to the expansion and contraction of metal cylinder 5.

With ultraviolet light emitting device 200 of this exemplary embodiment, metal cylinder 5 is held by holding component 6, on interposer 9 of substrate 2. Further, light emitting element 3 is disposed in an area surrounded by end 11c closer to substrate 2, of cylinder body 11 of metal cylinder 5, on interposer 9 of substrate 2. This allows metal cylinder 5 to shade ultraviolet light that travels outward in the radial direction of metal cylinder 5. This prevents ultraviolet light from illuminating holding component 6 disposed at the part of metal cylinder 5 closer to its outer circumference. Further, metal cylinder 5 can discharge heat generated from light emitting element 3. Resultingly, holding component 6 does not need to be made of a resin or a special metal having the radiation-resistant characteristic, for example, and thus an inexpensive resin material can be used for a holding component, thereby achieving a low-cost ultraviolet light emitting device. Further, the exemplary embodiment suppresses the influence (e.g., deterioration and degradation) of ultraviolet light on holding component 6, thereby achieving a highly reliable ultraviolet light emitting device.

With ultraviolet light emitting device 200 of this exemplary embodiment, holding component 6 is made of a resin, which further reduces the production cost compared to a case where holding component 6 is made of a metallic material.

With ultraviolet light emitting device 200 of this exemplary embodiment, flange 12 of metal cylinder 5 is fixed to the top of holding component 6. Accordingly, there is no opening between flange 12 and holding component 6, which prevents the generated ultraviolet light from being diffracted around metal cylinder 5 to reach substrate. This suppresses the influence of ultraviolet light on substrate 2.

With ultraviolet light emitting device 200 of this exemplary embodiment, flange 12 of metal cylinder 5 is fixed (e.g., elastically) to the top of supporting part 13 near insert hole 15 of holding component 6 through elastic bonding material 16. Accordingly, flange 12 can be fixed to the top of holding component 6 in a state where flange 12 and holding component 6 are slightly movable from each other. This allows a stress acting on metal cylinder 5 to be damped owing to the deformation for example of bonding material 16 even if holding component 6 expands and contracts. Consequently, the distortion of optical system 4 generated by the deformation and movement of holding component 6 can be effectively suppressed.

Further, the top of bonding material 16 that fixes flange 12 of metal cylinder 5 to holding component 6 enters a state covered with flange 12 of metal cylinder 5. This prevents ultraviolet light from illuminating bonding material 16. This suppresses the influence (e.g., deterioration and degradation) of ultraviolet light on bonding material 16.

With ultraviolet light emitting device 200 of this exemplary embodiment, opening 21 is provided between cylinder body 11 of metal cylinder 5 and holding component 6. This prevents holding component 6 from immediately contacting metal cylinder 5 even if holding component 6 expands. This allows a stress acting on metal cylinder 5 to be damped owing to opening 21 even if holding component 6 expands. Consequently, the distortion of optical system 4 generated by the deformation and movement of holding component 6 can be effectively suppressed.

With ultraviolet light emitting device 200 of this embodiment, reflector 7 plugs opening 20 between second open end 11b of cylinder body 11 and interposer 9. This prevents ultraviolet light generated from light emitting element 3 from leaking through opening 20 between substrate 2 and metal cylinder 5, thereby more reliably preventing ultraviolet light from illuminating holding component 6.

### Fourth Exemplary Embodiment

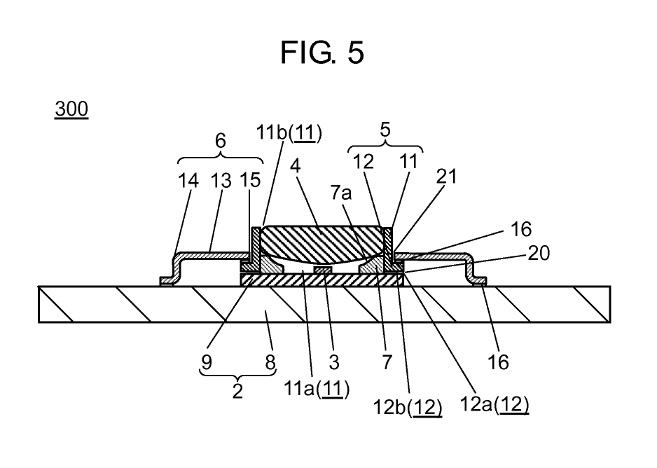

Hereinafter, a description is made of ultraviolet light emitting device 300 according to the fourth exemplary embodiment of the present invention, referring to FIG. 5.

FIG. 5 is a longitudinal sectional view of an ultraviolet light emitting device according to the fourth exemplary embodiment of the present invention.

Ultraviolet light emitting device 300 of this exemplary embodiment is different from ultraviolet light emitting device 1 of the first exemplary embodiment in that metal cylinder 5 is formed in an L-shape in a cross-sectional view shown in FIG. 5; and flange 12 is disposed facing interposer 9 of substrate 2 and is formed without wiring material 10. Otherwise, ultraviolet light emitting device 300 is the same as ultraviolet light emitting device 1 of the first exemplary embodiment. Hence, a component same as or similar to that of ultraviolet light emitting device 1 is given the same reference mark, and a description is made with the first exemplary embodiment quoted.

As shown in FIG. 5, ultraviolet light emitting device 300 of this exemplary embodiment is composed of light emitting element 3 provided on substrate 2, optical system 4 provided at a position facing light emitting element 3, metal cylinder 5 holding optical system 4, holding component 6 holding metal cylinder 5 on substrate 2, and reflector 7.

Note that light emitting element 3, optical system 4, and reflector 7 have basic structures same as those of the first exemplary embodiment.

Substrate 2 is composed of base substrate 8 and interposer 9. An electric circuit is built on base substrate 8 of substrate 2. Meanwhile, interposer 9 electrically connects light emitting element 3 with base substrate 8. In this case, although not shown in FIG. 5, base substrate 8 and interposer 9 are electrically connected with each other at a part where base substrate 8 composing substrate 2 and interposer 9 face each other. This results in light emitting element 3 disposed on interposer 9 of substrate 2 and base substrate 8 being electrically connect with each other. Here, interposer 9 of substrate 2 is fixed onto base substrate 8 through a conductive paste such as Ag paste.

Metal cylinder 5 includes tubular cylinder body 11 and flange 12 extending from cylinder body 11 outward in the radial direction, formed in an L-shape in a cross-sectional view shown in FIG. 5. Then, metal cylinder 5 is made of a metal (e.g., Kovar) having a coefficient of expansion identical to or substantially identical to that of optical system 4.

Cylinder body 11 of metal cylinder 5 has first open end 11a; and second open end 11b opposite to first open end 11a (closer to optical system 4), in the direction of the center line. Optical system 4 is inserted into second open end 11b of cylinder body 11. Then, opening 20 is provided between undersurface 12b of flange 12 (closer to first open end 11a of cylinder body 11) and interposer 9 of substrate 2. With this structure, flange 12 of cylinder body 11 faces interposer 9.

Flange 12 of metal cylinder 5 is provided on the entire outer circumference of cylinder body 11 closer to first open end 11a.

Holding component 6 is made of a resin such as Duracon or metal. Then, holding component 6, including supporting part 13 and fixing part 14, is provided facing base substrate 8 of substrate 2 and interposer 9. Supporting part 13 supports metal cylinder 5 from the outer circumference of cylinder body 11 of metal cylinder 5. Fixing part 14, connected to supporting part 13, is fixed onto base substrate 8 of substrate 2 through bonding material 16.

Further, supporting part 13 of holding component 6 is formed in a round plate shape in a planar view from above, similarly as described using FIG. 1, and has insert hole 15 piercing in the direction orthogonal (perpendicular) to the surface, in the central part of supporting part 13. The hole diameter of insert hole 15 is determined in a range larger than the outer circumference of cylinder body 11 of metal cylinder 5 and smaller than flange 12 of metal cylinder 5. With this setting, opening 21 is formed between supporting part 13 and cylinder body 11 inserted into insert hole 15.

When holding component 6 is inserted from second open end 11b through insert hole 15 of supporting part 13, along the outer circumferential surface of cylinder body 11 of metal cylinder 5, flange 12 of metal cylinder 5 is disposed so as to overlap the part around insert hole 15, of supporting part 13. Flange 12 is fixed to supporting part 13 (the part around insert hole 15, of supporting part 13) of holding component 6, at least in an area overlapping with flange 12 of metal cylinder 5, through elastic bonding material 16 such as silicone. With this structure, flange 12 of metal cylinder 5 is fixed to the top of holding component 6 slightly movably with respect to holding component 6 through bonding material 16.

Meanwhile, fixing part 14 of holding component 6 is provided on the entire outer circumferential edge of supporting part 13. Then, similarly to supporting part 13, fixing part 14 is fixed to base substrate 8 of substrate 2 through bonding material 16.

With the above process, ultraviolet light emitting device 300 of this exemplary embodiment is configured.

Hereinafter, a description is made of relationship between ultraviolet light generated from light emitting element 3 of ultraviolet light emitting device 300 and each component of ultraviolet light emitting device 300, of this exemplary embodiment, referring to FIG. 5.

First, similarly to ultraviolet light emitting device 1 of the first exemplary embodiment, of the ultraviolet light generated from light emitting element 3, the ultraviolet light heading toward reflector 7 is reflected on reflecting surface 7a of reflector 7. Then, the reflected ultraviolet light proceeds toward second open end 11b of cylinder body 11 of metal cylinder 5.

Meanwhile, of the ultraviolet light generated from light emitting element 3, the ultraviolet light that travels outward in the radial direction of metal cylinder 5 strikes the inner circumferential surface of metal cylinder 5, and undergoes reflection and diffusion to proceed toward second open end 11b of cylinder body 11 while changing its traveling direction.

Under all of the circumstances, the ultraviolet light generated from light emitting element 3 reaches optical system 4 without leaking from the inside of metal cylinder 5 to the outside around metal cylinder 5. Subsequently, the ultraviolet light passes through optical system 4 and is emitted from second open end 11b of cylinder body 11 of metal cylinder 5 toward the outside space.

As described above, with ultraviolet light emitting device 300 of this exemplary embodiment, metal cylinder 5 holding optical system 4 is made of a metal (e.g., Kovar) having a coefficient of expansion identical to or substantially identical to that of optical system 4. Accordingly, even if optical system 4 and metal cylinder 5 expand under the influence of temperature change caused by changes of the outside environment, metal cylinder 5 and optical system 4 expand and contract to the same extent. This prevents the distortion of optical system 4 due to the expansion and contraction of metal cylinder 5.

With ultraviolet light emitting device 300 of this exemplary embodiment, metal cylinder 5 is held by holding component 6, on interposer 9 of substrate 2. Further, light emitting element 3 is disposed in an area surrounded by flange 12 closer to substrate 2, of cylinder body 11 of metal cylinder 5, on interposer 9 of substrate 2. This allows metal cylinder 5 to shade ultraviolet light that travels outward in the radial direction of metal cylinder 5. This prevents ultraviolet light from illuminating holding component 6 disposed at the part of metal cylinder 5 closer to its outer circumference. Resultingly, holding component 6 does not need to be made of a special resin or a special metal, thereby achieving a low-cost ultraviolet light emitting device. Further, the exemplary embodiment suppresses the influence (e.g., deterioration and degradation) of ultraviolet light on holding component 6, thereby achieving a highly reliable ultraviolet light emitting device.

With ultraviolet light emitting device 300 of this exemplary embodiment, top surface 12a of flange 12 of metal cylinder 5 is fixed (e.g., elastically) to the bottom of supporting part 13 near insert hole 15 of holding component 6 through elastic bonding material 16. Accordingly, flange 12 can be fixed to the bottom of holding component 6 in a state where flange 12 and holding component 6 are slightly movable from each other. This allows a stress acting on metal cylinder 5 to be damped owing to the deformation for example of the bonding material even if holding component 6 expands. Consequently, the distortion of optical system 4 generated by the deformation and movement of holding component 6 can be suppressed.

With ultraviolet light emitting device 300 of this exemplary embodiment, opening 21 is provided between cylinder body 11 of metal cylinder 5 and holding component 6. This prevents holding component 6 from immediately contacting metal cylinder 5 even if holding component 6 expands. This allows a stress acting on metal cylinder 5 to be damped even if holding component 6 expands. Consequently, the distortion of optical system 4 generated by the deformation and movement of holding component 6 can be effectively suppressed.

With ultraviolet light emitting device 300 of this exemplary embodiment, reflector 7 plugs opening 20 between first open end 11a of cylinder body 11 and interposer 9. This prevents ultraviolet light generated from light emitting element 3 from leaking through opening 20 between substrate 2 and metal cylinder 5, thereby more reliably preventing ultraviolet light from illuminating holding component 6.

Note that an ultraviolet light emitting device of the present invention is not limited to the above-described first to fourth exemplary embodiments, but clearly, various types of modifications may be added within a scope that does not deviate from the gist of the present invention.

For example, in the first to fourth exemplary embodiments, the description is made using the example where light emitting element 3 is a UV-LED, but not limited to this example. Light emitting element 3 may be a light source (e.g., an excimer lamp) that generates ultraviolet light. This does not limit the type of a light source, thereby allowing an appropriate light source to be chosen according to a required size and light intensity of a light source.

In the first to fourth exemplary embodiments, the description is made using the example where flange 12 is provided on the entire outer circumference of cylinder body 11, but not limited to this example. For example, flange 12 may be provided on the outer circumference of cylinder body 11 in a discontinuous or discrete manner. This facilitates processing the flange.

In the first to fourth exemplary embodiments, the description is made using the example where fixing part 14 is provided on the entire outer circumference of supporting part 13, but not limited to this example. For example, fixing part 14 may be provided on the outer circumference of supporting part 13 in a discontinuous or discrete manner. This facilitates processing the flange. To reliably protect wiring material 10 for example from being illuminated by ultraviolet light, however, fixing part 14 is favorably provided on the entire outer circumferential edge of supporting part 13.

In the first to fourth exemplary embodiments, the description is made using the example where the hole diameter of insert hole 15 is determined in a range larger than the outer circumference of cylinder body 11 of metal cylinder 5 and smaller than flange 12 of metal cylinder 5, but not limited to this example. For example, the hole diameter of insert hole 15 may be determined as identical to or substantially identical to the outer circumference of cylinder body 11 of metal cylinder 5. To prevent expanded holding component 6 from immediately contacting metal cylinder 5 (i.e., expanded holding component 6 exerts a stress on metal cylinder 5), however, the hole diameter of insert hole 15 is favorably determined in a range larger than the outer circumference of cylinder body 11 of metal cylinder 5 and smaller than flange 12 of metal cylinder 5.

In the first to fourth exemplary embodiments, the description is made using the example where flange 12 is provided at first open end 11a of cylinder body 11, but not limited to this example. For example, flange 12 may be provided at second open end 11b of cylinder body 11 of metal cylinder 5. This allows connection without using a wiring material as shown hereinafter.

In the first to third exemplary embodiments, to provide flange 12 at second open end 11b of cylinder body 11, base substrate 8 and interposer 9 need to be electrically connected with each other without using wiring material 10, unlike in the fourth exemplary embodiment.

In the fourth exemplary embodiments embodiment, how to electrically connect base substrate 8 and interposer 9 with each other is not especially mentioned. Hence, a concrete connecting manner is exemplified below. For example, first, a pin is provided on interposer 9, and a socket into which the pin of interposer 9 can be inserted is provided on base substrate 8. Then, the pin of interposer 9 is inserted into the socket of base substrate 8 to provide a manner for electrically connecting the components with each other. Here, the above-described pin and socket may be provided opposite to each other, allowing the components to be connected in the same way.

Further, in the first to third exemplary embodiments, the description is made using the example where wiring material 10 is used to electrically connect base substrate 8 with interposer 9, but not limited to this example. For example, in the same way as the above-described fourth exemplary embodiment, a pin and a socket may be used for electrical connection. This eliminates the need for a wiring material to avoid a risk such as a break.

In the first, third, and fourth exemplary embodiments, the description is made using the example where reflector 7 is fitted to the inside of metal cylinder 5, but not limited to this example. For example, if the spaces inside and outside metal cylinder 5 can be partitioned off from each other, only reflecting surface 7a of reflector 7 may be made to be disposed in an area inside metal cylinder 5 on substrate 2. As a concrete example, metal cylinder 5 may be disposed so as to overlap the top surface of reflector 7 except for reflecting surface 7a. This prevents the diameter of metal cylinder 5 from being limited by the size of reflector 7.

### INDUSTRIAL APPLICABILITY

The present invention can be applied to an ultraviolet light emitting device for example that requires prevention of the distortion of the optical system and the deterioration and deformation of the holding component.

### REFERENCE MARKS IN THE DRAWINGS

1, 100, 200, 300 ultraviolet light emitting device
2 substrate
3 light emitting element
4 optical system
5 metal cylinder
6 holding component
7 reflector
7a reflecting surface
8 base substrate
9 interposer
10 wiring material
11 cylinder body
11a first open end
11b second open end
11c end
12 flange
12a top surface
12b undersurface
13 supporting part
14 fixing part
15 insert hole
16 bonding material
20, 21 opening

1. An ultraviolet light emitting device comprising:
a light emitting element provided on a substrate;
an optical system provided at a position facing the light emitting element;
a metal cylinder having an opening for holding the optical system; and
a holding component having an insert hole for holding the metal cylinder, on the substrate,
wherein the light emitting element is disposed in an area of the substrate, the area surrounded by one end of the metal cylinder closer to the substrate.

2. The ultraviolet light emitting device of claim 1,
wherein the metal cylinder has a tubular cylinder body and a flange extending from the cylinder body outward in a radial direction of the cylinder body, and
wherein the flange is fixed to the holding component.

3. The ultraviolet light emitting device of claim 2, wherein the flange is fixed to the holding component with a bonding material.

4. The ultraviolet light emitting device of claim 2, wherein an opening is provided between the cylinder body of the metal cylinder and the insert hole of the holding component.

5. The ultraviolet light emitting device of claim 1, wherein the end closer to the substrate, of the metal cylinder is in contact with the substrate.

6. The ultraviolet light emitting device of claim 1, further comprising a reflector having a reflecting surface surrounding a periphery of the light emitting element, wherein the reflector is provided in contact with the metal cylinder, near the end closer to the substrate.

7. The ultraviolet light emitting device of claim 1, further comprising a reflector having a reflecting surface surrounding a periphery of the light emitting element, wherein at least the reflecting surface of the reflector is provided in an area of the substrate, the area surrounded by the end of the metal cylinder closer to the substrate.

8. The ultraviolet light emitting device of claim 1, wherein the holding component is made of resin.

9. The ultraviolet light emitting device of claim 1, wherein the optical system is provided so as to plug the opening of the metal cylinder.
